(19) United States
(12) Patent Application Publication
(10) Pub. No.: US 2020/0379524 A1
(43) Pub. Date: Dec. 3, 2020

(54) WATER-COOLED HEAT DISSIPATION DEVICE

(71) Applicant: THERMALTAKE TECHNOLOGY CO., LTD., Taipei City (TW)

(72) Inventor: Pei-Hsi Lin, Taipei City (TW)

(21) Appl. No.: 16/535,328

(22) Filed: Aug. 8, 2019

(30) Foreign Application Priority Data
May 27, 2019 (TW) 108206693

(51) Int. Cl. G06F 1/20; H05K 7/20; F21V 33/00

(52) U.S. Cl. CPC G06F 1/20; H05K 7/20272; G06F 2200/201; H05K 7/20263; H05K 7/20254; F21V 33/0052

(57) ABSTRACT

A water-cooled heat dissipation device includes a processor water-cooled head, a water-cooled bar and a memory water-cooled head. The processor water-cooled head is connected to the water-cooled bar by a first pipe. The water-cooled bar is connected to the memory water-cooled head by a second pipe. The memory water-cooled head is connected to the processor water-cooled head by a third pipe. The processor water-cooled head drives cooling water to circulate and flow through the processor water-cooled head, the water-cooled bar and the memory water-cooled head.

### CROSS-REFERENCE TO RELATED APPLICATION

This non-provisional application claims priority under 35 U.S.C. § 119(a) on Patent Application No(s). 108206693 filed in Taiwan, R.O.C. on May 27, 2019, the entire contents of which are hereby incorporated by reference.

### BACKGROUND OF THE INVENTION

### 1. Field of the Invention

The present disclosure relates to water-cooled heat dissipation device, and in particular to a water-cooled heat dissipation device for effecting circulatory heat dissipation of a processor and a memory synchronously.

### 2. Description of the Related Art

High-performance integrated circuit chips inevitably generate much heat when operating at a high speed or accessing/processing plenty of data. If the heat is not instantly removed or dissipated, the resultant high temperature will shorten the service life of the chips and deteriorate their operation performance. Therefore, it is important to provide a multi-chip, synchronous (simultaneous) heat dissipation solution to preclude high-temperature overheating, effectively maintain operation performance, extend service life, and save power.

### BRIEF SUMMARY OF THE INVENTION

To overcome the aforesaid drawback of the prior art, an objective of the present disclosure is to provide a water-cooled heat dissipation device for effecting circulatory heat dissipation of a processor and a memory synchronously to enhance heat dissipation efficiency, maintain operation performance of the processor and the memory, extend their service life, and save power.

To achieve at least the above objective, the present disclosure provides a water-cooled heat dissipation device comprising a processor water-cooled head, a water-cooled bar and a memory water-cooled head. The processor water-cooled head is connected to the water-cooled bar by a first pipe. The water-cooled bar is connected to the memory water-cooled head by a second pipe. The memory water-cooled head is connected to the processor water-cooled head by a third pipe. The processor water-cooled head drives cooling water to flow through the processor water-cooled head, the water-cooled bar and the memory water-cooled head. The water-cooled bar has therein a plurality of metallic cooling fins.

In an embodiment of the present disclosure, the processor water-cooled head comprises an upper cover, a pump and a base board, the pump is disposed between the upper cover and the base board and connected to the base board by a channel, wherein the base board and the pump each have a first connection opening, one connected to the first pipe, and the other connected to the third pipe.

In an embodiment of the present disclosure, the base board is a metallic board.

In an embodiment of the present disclosure, the memory water-cooled head comprises a top cover, a washer, a bottom board and a thermal transfer medium such that the top cover, the washer and the bottom board are fitted together to form a water chamber, and the thermal transfer medium is disposed at a bottom of the bottom board.

In an embodiment of the present disclosure, the bottom board is a metallic board.

In an embodiment of the present disclosure, the memory water-cooled head comprises two second connectors, the second connectors are connected to the top cover so as to be in communication with the water chamber, and the second connectors are connected to the third pipe and the second pipe, respectively.

In an embodiment of the present disclosure, the memory water-cooled head has at least one light-emitting component.

Therefore, the present disclosure provides a water-cooled heat dissipation device for effecting circulatory heat dissipation of a processor and a memory synchronously to enhance heat dissipation efficiency, maintain operation performance of the processor and the memory, extend their service life, and save power.

### BRIEF DESCRIPTION OF THE DRAWINGS

FIG. 1 is a schematic view of a water-cooled heat dissipation device according to a preferred embodiment of the present disclosure.

FIG. 2 is a top view of the water-cooled heat dissipation device according to a preferred embodiment of the present disclosure.

FIG. 3 is a schematic view of a processor water-cooled head of the water-cooled heat dissipation device according to a preferred embodiment of the present disclosure.

FIG. 4 is an exploded view of a memory water-cooled head of the water-cooled heat dissipation device according to a preferred embodiment of the present disclosure.

FIG. 5 is a schematic view of the memory water-cooled head of the water-cooled heat dissipation device according to a preferred embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

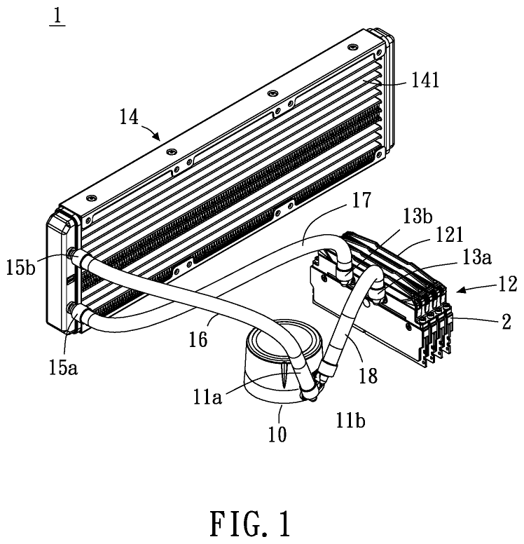

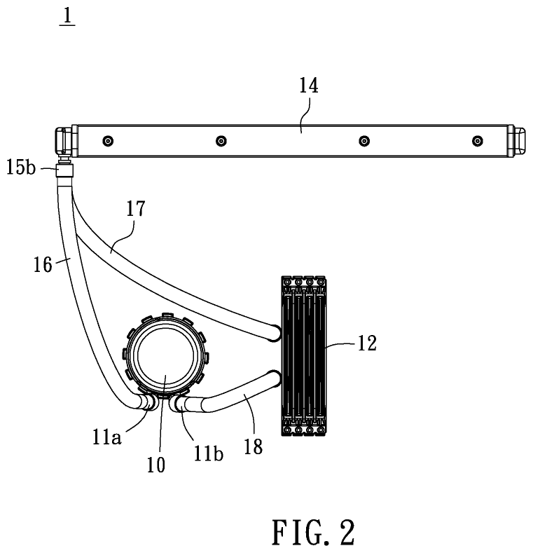

Referring to FIG. 1 and FIG. 2, the present disclosure provides a water-cooled heat dissipation device 1 which comprises a processor water-cooled head 10, a memory water-cooled head 12, a water-cooled bar 14, a first pipe 16, a second pipe 17 and a third pipe 18. The first pipe 16 connects the processor water-cooled head 10 and the water-cooled bar 14. The second pipe 17 connects the water-cooled bar 14 and the memory water-cooled head 12. The third pipe 18 connects the memory water-cooled head 12 and the processor water-cooled head 10. Cooling water is driven by the processor water-cooled head 10 to flow from the processor water-cooled head 10 to the water-cooled bar 14 via the first pipe 16 and then flow to the memory water-cooled head 12 via the second pipe 17. Finally, the cooling water returns to the processor water-cooled head 10 via the third pipe 18. The cooling water may also circulate by flowing reversely.

Referring to FIG. 1 and FIG. 2, the processor water-cooled head 10 comprises two first connectors 11a, 11b. The memory water-cooled head 12 comprises two second connectors 13a, 13b. The water-cooled bar 14 comprises two third connectors 15a, 15b. The first connector 11a of the processor water-cooled head 10 is connected to the third connector 15b of the water-cooled bar 14 via the first pipe 16. The third connector 15a of the water-cooled bar 14 is connected to the second connector 13b of the memory water-cooled head 12 via the second pipe 17. The second connector 13a of the memory water-cooled head 12 is connected to the first connector 11b of the processor water-cooled head 10 via the third pipe 18.

As described above, the processor water-cooled head 10 is disposed on a processor (not shown), and the memory water-cooled head 12 is disposed on a memory module 2. The processor water-cooled head 10 uses the cooling water to absorb heat generated by the processor and drives the cooling water which has absorbed the heat to flow to the water-cooled bar 14 via the first pipe 16, so as to transfer the heat to the water-cooled bar 14 for heat dissipation. With the processor water-cooled head 10 operating, the cooling water which has been cooled by the water-cooled bar 14 because of heat dissipation flows to the memory water-cooled head 12 via the second pipe 17. Upon its arrival at the memory water-cooled head 12, the cooling water absorbs the heat generated by the memory module 2, and then the cooling water is driven by the processor water-cooled head 10 to return to the processor water-cooled head 10 via the third pipe 18, thereby finalizing the circulation of the cooling water. The cooling water may also circulate by flowing reversely. Therefore, the present disclosure provides a water-cooled heat dissipation device for effecting circulatory heat dissipation of a processor and a memory synchronously to enhance heat dissipation efficiency, maintain operation performance of the processor and the memory, extend their service life, and save power.

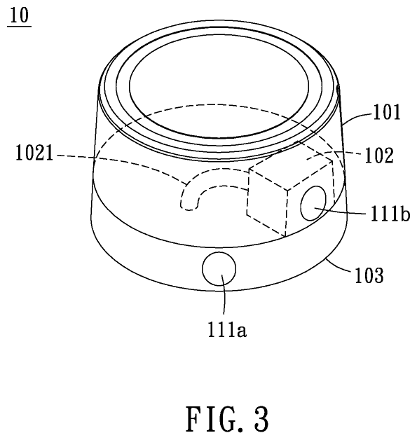

Referring to FIG. 1 and FIG. 3, in an embodiment of the present disclosure, the processor water-cooled head 10 comprises an upper cover 101, a pump 102 and a base board 103. The pump 102 is disposed between the upper cover 101 and the base board 103. The pump 102 is connected to the base board 103 by a channel 1021. The base board 103 and the pump 102 each have a first connection opening 111a, 111b. The first connection opening 111a is connected to the first pipe 16 by the first connector 11a. The other first connection opening 111b is connected to the third pipe 18 by the upper cover 101 and the other first connector 11b. The base board 103 is in contact with a processor (not shown). The base board 103 is a metallic board with high thermal conductivity, for example, a copper board. Therefore, the processor water-cooled head 10 drives the cooling water to flow and circulate, whereas the base board 103 absorbs heat generated by the processor and then transfers the heat to the cooling water.

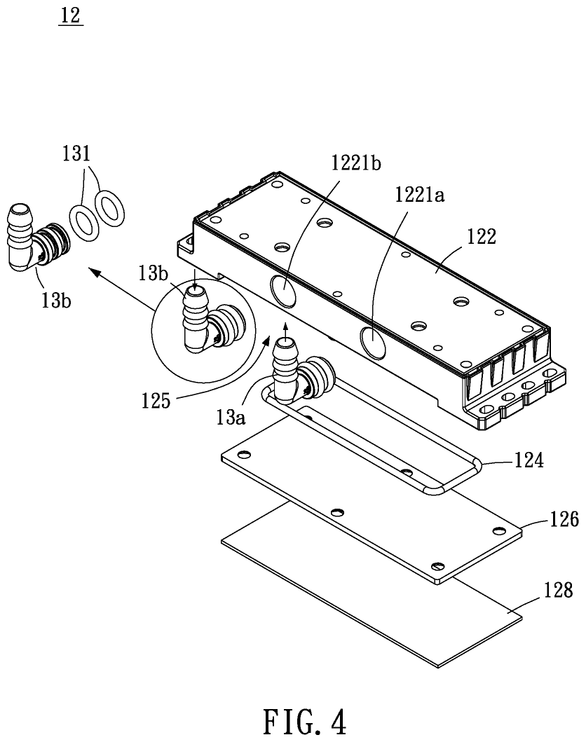

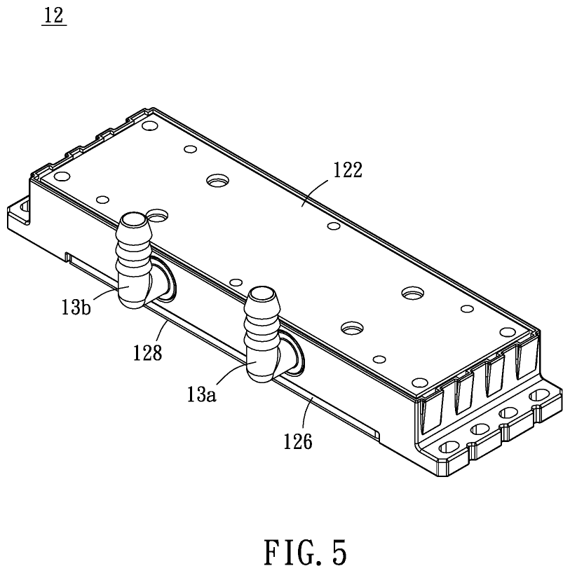

Referring to FIG. 1, FIG. 4 and FIG. 5, in an embodiment of the present disclosure, the memory water-cooled head 12 not only comprises two second connectors 13a, 13b but also comprises a top cover 122, a washer 124, a bottom board 126 and a thermal transfer medium 128 (liquid-state or solid-state). The top cover 122, washer 124 and bottom board 126 are fitted together to form a water chamber 125. The thermal transfer medium 128 is disposed at the bottom of the bottom board 126. The two second connectors 13a, 13b are connected to two second connection openings 1221a, 1221b of the top cover 122, respectively, so as to be in communication with the water chamber 125, wherein leakage of cooling water is prevented with an O-ring 131. The two second connectors 13a, 13b are connected to the third pipe 18 and the second pipe 17, respectively. The bottom board 126 is a metallic board with high thermal conductivity, such as a copper board. The memory water-cooled head 12 is disposed on the memory module 2 through the thermal transfer medium 128. Heat generated by the memory module 2 is transferred to the cooling water in the water chamber 125 through the thermal transfer medium 128 and the bottom board 126.

Referring to FIG. 4 and FIG. 5, in an embodiment of the present disclosure, the memory water-cooled head 12 has at least one light-emitting component 121 as needed. The location and quantity of the light-emitting component 121 are decided by users.

The water-cooled heat dissipation device of the present disclosure uses a processor water-cooled head to dissipate heat from a processor and drive circulation of cooling water simultaneously, allowing the water-cooled bar, processor water-cooled head and memory water-cooled head to effect circulatory heat dissipation of the processor and memory synchronously, so as to effectively enhance heat dissipation efficiency, maintain operation performance of the processor and memory, extend their service life and save power.

While the present disclosure has been described by means of specific embodiments, numerous modifications and variations could be made thereto by those skilled in the art without departing from the scope and spirit of the present disclosure set forth in the claims.

What is claimed is:

1. A water-cooled heat dissipation device, comprising:
a processor water-cooled head;
a water-cooled bar having therein a plurality of metallic cooling fins and connected to the processor water-cooled head by a first pipe; and
a memory water-cooled head connected to the water-cooled bar by a second pipe and connected to the processor water-cooled head by a third pipe, wherein the processor water-cooled head drives cooling water to flow through the processor water-cooled head, the water-cooled bar and the memory water-cooled head.

2. The water-cooled heat dissipation device of claim 1, wherein the processor water-cooled head comprises an upper cover, a pump and a base board, the pump is disposed between the upper cover and the base board and connected to the base board by a channel, wherein the base board and the pump each have a first connection opening, one connected to the first pipe, and another connected to the third pipe.

3. The water-cooled heat dissipation device of claim 2, wherein the base board is a metallic board.

4. The water-cooled heat dissipation device of claim 1, wherein the memory water-cooled head comprises a top cover, a washer, a bottom board and a thermal transfer medium such that the top cover, the washer and the bottom board are fitted together to form a water chamber, and the thermal transfer medium is disposed at a bottom of the bottom board.

5. The water-cooled heat dissipation device of claim 4, wherein the bottom board is a metallic board.

6. The water-cooled heat dissipation device of claim 4, wherein the memory water-cooled head comprises two second connectors, the second connectors are connected to the top cover so as to be in communication with the water chamber, and the second connectors are connected to the third pipe and the second pipe, respectively.

7. The water-cooled heat dissipation device of claim 4, wherein the memory water-cooled head has at least one light-emitting component.
